(19) United States
(12) Patent Application Publication
(10) Pub. No.: US 2004/0155702 A1
(43) Pub. Date: Aug. 12, 2004

(54) Active filter circuit arrangement

(75) Inventor: Peter Danielsson, Solna (SE)

Correspondence Address: SCHIFF HARDIN, LLP, PATENT DEPARTMENT, 6600 SEARS TOWER, CHICAGO, IL, 60606-6473, US

(73) Assignee: Siemens Elema AB

(21) Appl. No.: 10/364,478

(22) Filed: Feb. 11, 2003

(51) Int. Cl. H03B 1/00; H04B 1/10; H03K 5/00

(52) U.S. Cl. 327/552

(57) ABSTRACT

An active filter circuit for removing high frequency noise from an input signal, particularly RF noise from an ECG signal, has an active first circuit having an input and an output, an RC-filter network arranged in electrical connection with the input and a second circuit connected in a positive feedback loop with the RC-filter network and adapted to reduce high frequency signals at an output of the first active circuit.

### BACKGROUND OF THE INVENTION

1. Field of the Invention

The present invention relates to an active filter circuit arrangement and in particular to an active filter circuit arrangement capable of suppressing relatively high voltage, high frequency signals.

2. Description of the Prior Art

It is often required to obtain and measure relatively low voltage, low frequency signals in the presence of relatively high voltage, high frequency signals. A particular example is the measurement of electrocardiograph (ECG) signals in the presence of ablation signals or other radio frequency noise. Very often the same catheter electrodes that are used to record ECG are also used to deliver ablation energy. The signal received by such electrodes will contain an ECG signal on the order of a few mV and at a frequency around 10 Hz together with a signal on the order of 100 V and at a frequency of typically around 500 kHz (for ablation signals). In practice, the filter employed to suppress the high frequency noise therefore must be capable of reducing its amplitude by more than 140 decibels in order to obtain a usable ECG signal. Despite the large difference in frequencies between the ECG signal and the noise the use of a second or preferably higher order filter is needed.

It is known to realize higher order filters (n>1) using an active filter circuit, one example being a Sallen-Key type filter circuit, generally having a passive RC-filter network connected between the signal input and an input of an operational amplifier or other active circuit, and having an output at which the filtered signal will be provided. This active circuit is typically arranged with its output also connected in a positive feedback loop with the RC filter network. However, in order to reduce the noise level sufficiently an amplifier with a high performance at high frequencies is required. Such an amplifier typically has poor low frequency characteristics and so is not well suited to the measurement of ECG, or other low frequency, signals.

Alternatively, if an amplifier having good low frequency characteristics is used in the known active filter circuit then high frequency noise that results from the poor high frequency characteristics of such an amplifier will be present at its output, or even worse the poor high frequency characteristics may cause such an amplifier to generate frequency noise which will then be present at its output when a high frequency component is present at its input.

### SUMMARY OF THE INVENTION

An object of the present invention is to provide an active filter circuit having improved low frequency characteristics and high frequency noise suppression.

The above object is achieved in accordance with the invention having an active first circuit with at least one input and at least one output, and RC-filter network in electrical connection with one of the inputs, and a second circuit connected in a positive feedback loop with the RC filter network, which reduces high-frequency signals at an output of the active first circuit.

By providing the second circuit, which may be active or passive, connected in a positive feedback loop with the active first circuit, preferably having an operational amplifier as an active component, to reduce high frequency signals at the output of the active first circuit, then an amplifier having good low frequency characteristics may be used in the active first circuit.

### DESCRIPTION OF THE DRAWINGS

FIG. 1 shows an active filter circuit forming a second order filter in accordance with the invention.

FIG. 2 shows an active filter circuit forming a third order filter with gain in accordance with the invention.

FIG. 3 shows an active filter circuit forming a third order filter with gain having a reduced number of components in accordance with the invention.

FIG. 4 shows an active filter circuit forming a third order filter with gain having an alternative feed back loop connection in accordance with the invention.

FIG. 5 shows an alternative active filter circuit forming a third order filter in accordance with the invention.

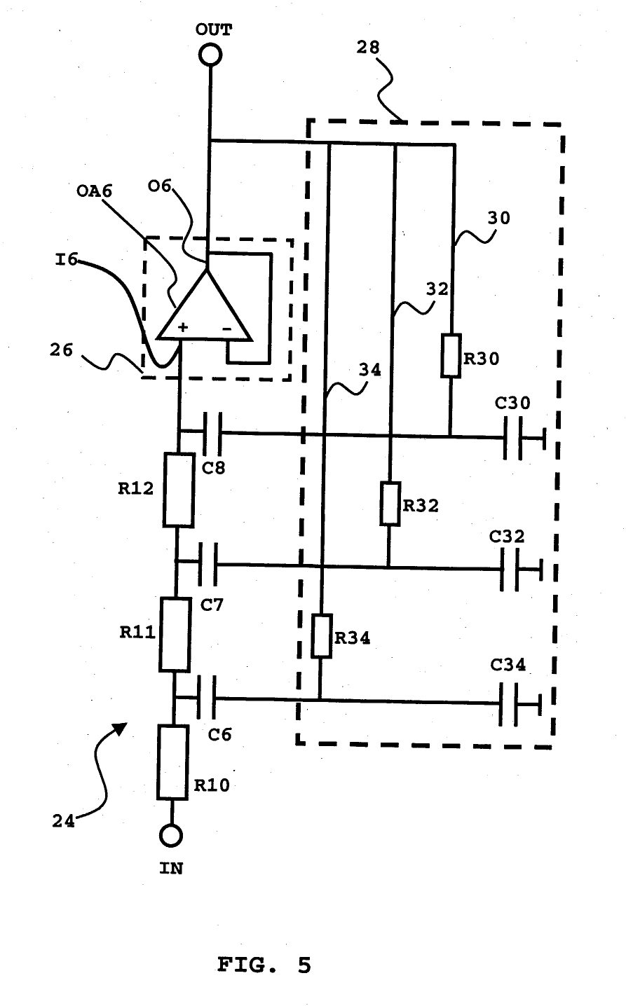

### DESCRIPTION OF THE PREFERRED EMBODIMENTS

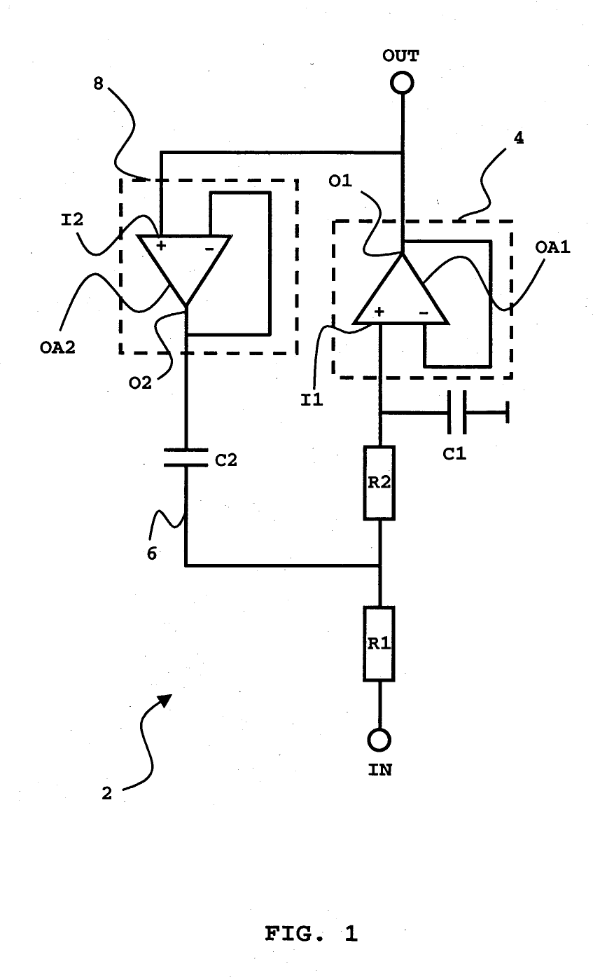

The active filter circuit 2 of a second order filter is shown schematically in FIG. 1. An RC-filter network formed by resistors R1,R2 and capacitors C1,C2 is connected to a positive input 11 of a first operational amplifier OA1 of an active first circuit 4. It will be appreciated that although illustrated and referred to as single components the resistors and capacitors may be any number of individual passive (fixed or variable) components configured and selected to provide the desired total resistance or capacitance necessary for the proper operation of the network.

The operational amplifier OA1 is connected in a unity gain arrangement and has an output O1 that is connected to the output, OUT, of the active filter circuit 2 and also in a positive feedback loop 6 with the capacitor C2 of the RC-filter network R1,R2,C1,C2. This arrangement will be recognized by those skilled in the art as a known Sallen-Key second order low pass filter. A second electrical circuit 8, here including an active component in the form of second operational amplifier OA2 configured for unity gain, is connected in the feedback loop 6 connecting the first active circuit 4 to the RC-filter network R1,R2,C1,C2. The second operational amplifier OA2 is arranged in the feedback loop 6 with its output O2 connected to the capacitor C2 of the filter network and its input 12 connected to the output O1 of the first operational amplifier OA1.

In use, when a signal having both high and low frequency components, such as an ECG signal having RF noise picked up from for example a 500 kHz ablation signal, is applied to the input IN of the filter circuit 2 then capacitors C1,C2 will effectively appear as open circuits to the low frequency components which will be buffered by the operational amplifier OA1 of the active first circuit 4 to appear at the output OUT of the active filter circuit 2. These capacitors C1,C2 will effectively appear as short circuits to the high frequency components which are therefore shunted to ground through the capacitor C1 at the input I1+ of the operational amplifier OA1 so that no signal should appear at its output O1. However, in the conventional Sallen-Key active filter that is described above some of the high frequency signals may pass via the capacitor C2 in the feedback loop and appear at the output O1 and propagate to the output OUT of the active filter circuit 2. When the high frequency current coming from C2 goes into the output 11 of amplifier OA1 the relatively high output impedance of OA1 at high frequencies converts the current into a voltage that appears at the output O1. To prevent this the operational amplifier OA2 of the second electrical circuit 6 is arranged such that the high frequency signals are blocked from appearing at the output O1 of the first operational amplifier OA1. The current from C2 goes via OA2 to OA2 power supply (not shown).

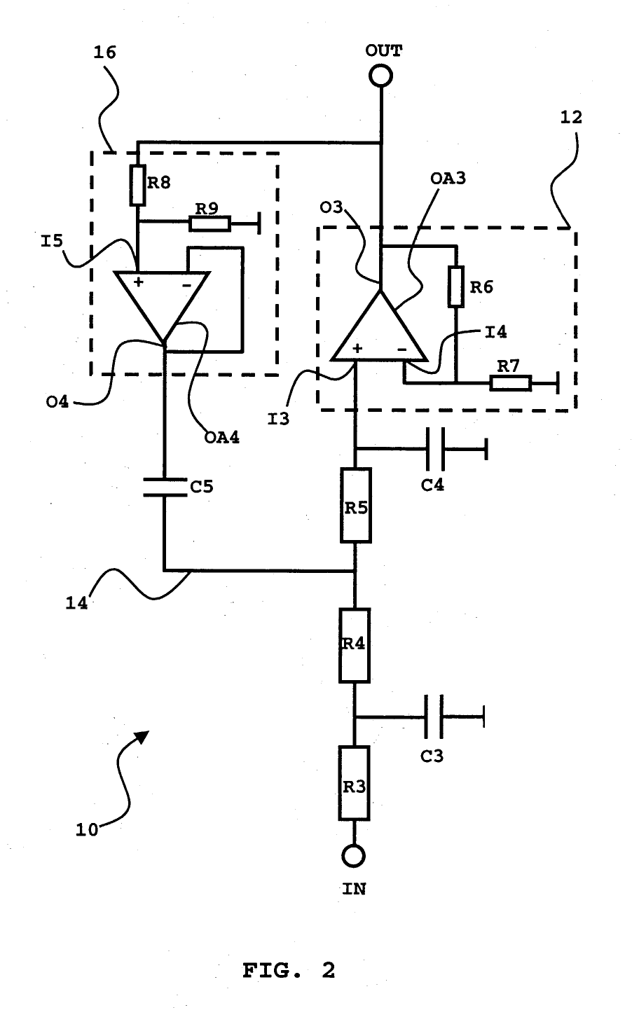

An active filter circuit 10 of a third order filter with gain, which is shown schematically in FIG. 2. An RC-filter network formed by resistors R3,R4,R5 and capacitors C3,C4,C5 is connected to a positive input I3 of a first operational amplifier OA3 of an active first circuit 12. The operational amplifier OA3 is connected in a positive gain arrangement having an amplification determined by the resistors R6,R7 connected to the negative input 14 and has an output O3 that is connected to the output OUT of the active filter circuit 10 and also in a positive feedback loop 14 with the capacitor C5 of the RC-filter network R3,R4,R5,C3,C4,C5. A second electrical circuit 16 in the present embodiment has an active component, here in the form of second operational amplifier OA4, configured in a positive, less than one, gain arrangement with resistors R8,R9 to provide a signal at its output O4 having an amplitude reduced by the factor by which the signal at the output O3 of the first operational amplifier OA3 is increased. The second operational amplifier OA4 is connected in the feedback loop 14 with its output O4 connected to the capacitor C5 of the filter network R3,R4,R5,C3,C4,C5 and its input 15 connected to the output O3 of the first operational amplifier OA3.

In use the second electrical circuit 16 performs in a manner identical to the second electrical circuit 8 of FIG. 1 to prevent the appearance of high frequencies at the output O3 of the first operational amplifier OA3 of the active first circuit 12 which would otherwise pass via the feedback loop 14.

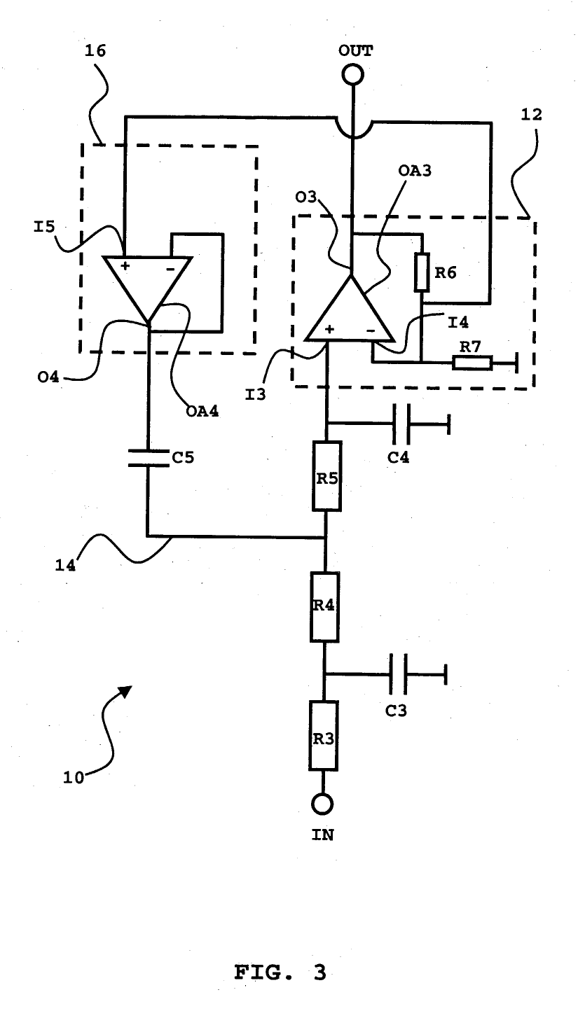

A refinement to the embodiment of the third order filter circuit 10 that is shown in FIG. 2 is shown in FIG. 3 having a reduced number of components compared to the embodiment 10 of FIG. 2. The resistors R8,R9 of the second electric circuit 16 are removed in the embodiment of FIG. 3 and their function performed by the resistors R6,R7 of the active first circuit 12. This is achieved by connecting the input 15 of the second operational amplifier OA4 to the output O3 of the first operational amplifier OA3 between the resistors R6,R7, as shown.

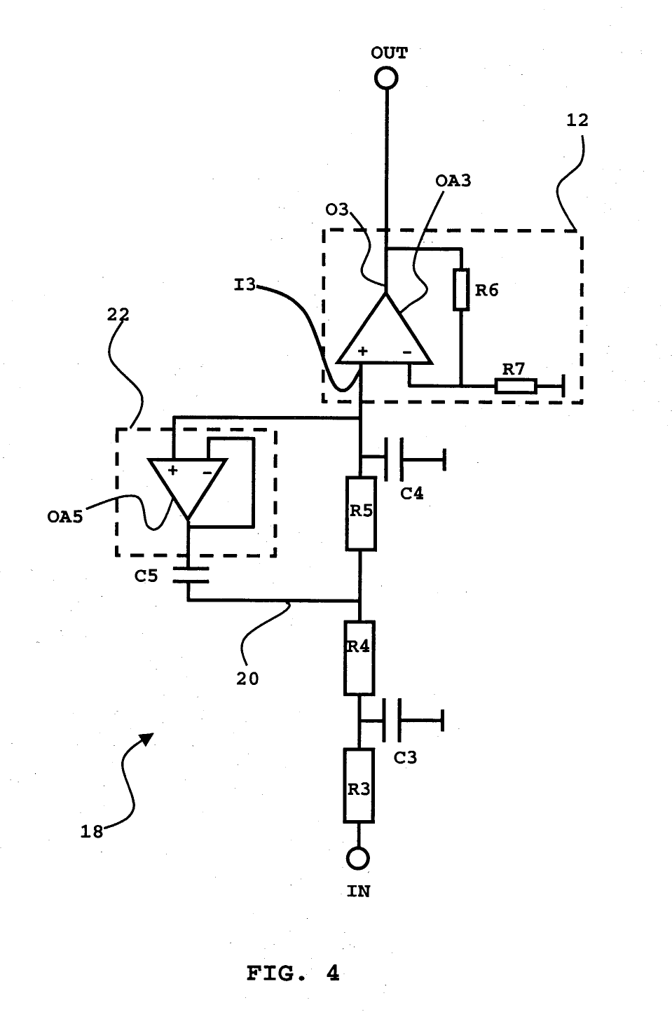

A second embodiment of an active filter circuit 18 of a third order filter with gain, which is shown schematically in FIG. 4 in which components common to the embodiment of FIGS. 2 and 3 are provided with the same reference indices. An RC-filter network is shown that is essentially the same as that network R3,R4,R5,C3,C4,C5 described in relation to FIG. 2, and is connected to an input 13 of an active first circuit 12, having an operational amplifier OA3 configured in a conventional manner to provide a positive gain determined by resistors R6,R7. Different from the third order filter circuit 10 that was described in relation to FIG. 2, the output O3 is connected only to the output OUT of the active filter circuit 18 and not to any feedback loop. Also different from the circuit 10 described in relation to FIG. 2 is that the active filter circuit 18 of FIG. 3 is provided with a feedback loop 20 which connects the input 13 of the first active circuit 12 to the RC-filter network R3,R4,R5,C3,C4,C5 via the capacitor C5. A second electrical circuit 22, here having an operational amplifier OA5 configured for unity gain, is connected to the feedback loop 20 and is configured to operate essentially in a manner as described above with reference to the second electrical circuits 8,16 of FIGS. 1 and 2 respectively, to isolate the input I3 of the first active circuit 12 from high frequency components of a signal applied to the input IN of the active filter circuit 18 that may appear in the feedback loop 20 when the capacitor C5 acts as an effective short circuit.

A further embodiment of an active filter circuit 24 of a third order filter is shown schematically in FIG. 4. An RC-filter network formed by resistors R10,R11,R12 and capacitors C6,C7,C8 is connected to an input 16 of a first active circuit 26 which here consists of an operational amplifier OA6 configured for unity gain. An output 06 of the amplifier OA6 is connected to the output of the active filter circuit 24 and to a second electrical circuit 28 which is configured to establish a positive feedback to the RC-filter network R10,R11,R12,C6,C7,C8, in this embodiment using only passive components. The second electrical circuit 28 is, in the present embodiment, configured to provide a separate feedback loop connection 30,32,34 between the output 06 of the amplifier OA6 and each capacitor C6,C7,C8 of the RC-filter network R10,R11,R12,C6,C7,C8.

Each feedback loop 30,32,34 includes a resistor/capacitor arrangement R30,C30;R32,C32;R34,C34 and arrangement functions in a similar manner to isolate the output O6 from high frequency components of a signal at the input IN of the active filter arrangement 24 that may appear in the feedback loop 30,32,35.

The second circuit 28 is illustrated with several feedback paths, however it can be modified to have only one feedback path. If resistors R34 and R30 are deleted the circuit topology will be very close to circuit 10, if it had unity gain, and if the values of R32 and C32 are selected to appropriate values. Then high frequency current will be shunted to ground via C32, and C7 will be essentially connected to the output of OA6 via R32 at ‘mid’ frequencies and at low frequencies C7 will be open.

It will be appreciated that the number of feedback paths is not important for the present invention. However it is essential that each feedback path is provided with a circuit, passive or active, to prevent high frequency signals from going to the output of the first active circuit.

Although modifications and changes may be suggested by those skilled in the art, it is the intention of the inventor to embody within the patent warranted hereon all changes and modifications as reasonably and properly come within the scope of his contribution to the art.

I claim as my invention:

1. An active filter circuit arrangement comprising:
an active first circuit having an input and an output;
an RC-filter network in electrical connection with said input, and a second circuit connected in a positive feedback loop with said RC filter network for reducing high-frequency signals at said output of said active first circuit.

2. An active filter circuit arrangement as claimed in claim 1 wherein said active first circuit comprises a plurality of inputs, including said input, and a plurality of outputs, including said output, and wherein said RC filter network is in electrical connection with one of said plurality of inputs, and wherein said second circuit in said positive feedback loop with said RC filter network reduces high-frequency signals at one of said plurality of outputs of said active first circuit.

3. An active filter circuit arrangement as claimed in claim 1 wherein said output of said active first circuit is connected in said positive feedback loop, and wherein said second circuit blocks passage of high-frequency signals to said output via said feedback loop.

4. An active filter circuit arrangement as claimed in claim 3 wherein said second circuit comprises an operation amplifier having an output connected to the RC filter network and an input connected to said output of said active first circuit.

5. An active filter circuit arrangement as claimed in claim 1 wherein said second circuit is connected in said positive feedback loop to said input of said active first circuit.

6. An active filter circuit arrangement as claimed in claim 1 wherein said second circuit is an active circuit.

7. An active filter circuit arrangement as claimed in claim 1 wherein said second circuit is a passive circuit.
